(19) United States
(12) Patent Application Publication
(10) Pub. No.: US 2026/0310841 A1
(43) Pub. Date: Oct. 8, 2026

(54) TEST APPARATUS FOR SIMULATING SUPPLY CONDITIONS OF A VEHICLE

(71) Applicant: IACOBUCCI HF AEROSPACE S.P.A., Ferentino (IT)

(72) Inventor: Lucio IACOBUCCI, Ferentino (IT)

(73) Assignee: IACOBUCCI HF AEROSPACE S.P.A., Ferentino (IT)

(21) Appl. No.: 19/639,741

(22) Filed: Apr. 6, 2026

(30) Foreign Application Priority Data
Apr. 8, 2025 (IT) 102025000007668

(51) Int. Cl. G06F 30/15

(52) U.S. Cl. CPC G06F 30/15

(57) ABSTRACT

A test apparatus for simulating supply conditions of a vehicle in order to test user devices intended to operate on board the vehicle, including: a portable support body, an electrical supply unit integrated into the support body and configured to electrically supply one or more user devices according to controllable and settable operating parameters so as to simulate the same electrical supply conditions present in the vehicle, and a hydraulic supply-discharge unit integrated into the support body and configured to supply water to a user device of the one or more user devices according to further operating parameters that are controllable and settable so as to simulate the same supply-discharge conditions present in the vehicle, and to recover water used by the user device.

### BACKGROUND OF THE INVENTION

The invention relates to a test apparatus for simulating actual supply conditions of a vehicle in order to test user devices intended to operate on board the vehicle.

More specifically, although not exclusively, the test apparatus according to the invention may be used to simulate the electrical and hydraulic supply conditions that may be found on board a vehicle.

The term “vehicle” is intended to mean a means of transport used in the aerospace field (for example an aeroplane), the nautical field (for example a yacht), the terrestrial field (such as a camper van), and the like.

In the following description, explicit reference will be made to the use of the test apparatus with user devices employed on an aeroplane, without thereby losing generality. Such user devices may include, by way of non-limiting example, a beverage-preparation machine (coffee machine), an electric oven (for example an induction oven) for preparing meals, a waste compactor, and the like.

### PRIOR ART

It is known to use an electric current transformer of the type used in laboratories to test user devices intended to operate on board a vehicle, for example during the design, fine-tuning and testing phases of such user devices. Indeed, such devices may operate with a three-phase electrical supply, unlike the single-phase supply used in domestic environments, and with voltage and frequency values different from those provided by domestic power utilities and which depend on the specific vehicle.

The electric current transformer of the known art has the drawback of being relatively bulky and heavy. This drawback makes the known-art transformer scarcely flexible when it needs to be transferred and used in different locations, for example to follow temporary events (such as fairs or exhibitions) for demonstrating the operation of said user devices.

Moreover, the electric current transformer of the known art is difficult to use for an unskilled operator who is responsible for demonstrating its operation. In fact, the known-art transformer provides numerous possibilities for adjusting the electrical supply conditions, which are not always intuitive.

Furthermore, the electric current generator of the known art is unsuitable for testing a user device intended for preparing certain beverages, such as coffee, which requires the use of water.

A further disadvantage, deriving from the difficulty or impossibility of using the known-art generating apparatus, particularly for testing user devices “on the ground” (i.e. not on board the vehicle), concerns in particular the use of a user device intended for preparing a meal, such as an oven of the type installable on board an aeroplane, or for preparing a beverage, such as a coffee machine. For the reasons set out above, the creation of recipes and the cooking tests for meals, as well as the beverage-preparation tests, are performed using conventional devices, such as professional ovens or coffee machines. Such conventional devices have characteristics (dimensions, operating parameters, etc.) that may be very different from those of user devices intended to operate on board a vehicle. These latter devices are indeed designed in particular to be lightweight—so as to reduce the fuel consumption of the vehicle—and compact, in order to maximise the available space on board the vehicle itself.

The use of conventional devices to prepare food intended to be served on board a vehicle results in the prepared food having physical characteristics (such as temperature distribution, humidity, consistency) and organoleptic (aromatic) characteristics different from the corresponding food prepared with the user devices intended to be used on board a vehicle; this leads to a loss of food quality, resulting in consumer dissatisfaction and waste of economic resources for the food-service provider.

It is therefore clear that the known-art apparatuses are disadvantageous in certain contexts and events.

In light of the above, it would be desirable to have a test apparatus that allows simulation of the actual supply conditions available on board a vehicle and that allows operation of any user device intended to operate on board the vehicle in an environment external to the vehicle itself.

### Objects of the Invention

An object of the invention is to improve existing test apparatuses for simulating actual supply conditions of a vehicle in order to test user devices intended to operate on board the vehicle.

Another object is to provide a test apparatus that can be easily transported from one place to another.

A further object is to provide a test apparatus that is structurally simple and easy for a user to operate.

A still further object is to provide a test apparatus capable of faithfully simulating actual supply conditions of a vehicle so as to test user devices intended to operate on board the vehicle, thereby improving their performance and the quality of the service and product provided by such user devices.

These and further objects are achieved by means of a test apparatus as defined in the appended claims.

### BRIEF DESCRIPTION OF THE INVENTION

The invention may be better understood and carried into effect with reference to the accompanying drawings, which illustrate an exemplary and non-limiting embodiment thereof, in which:

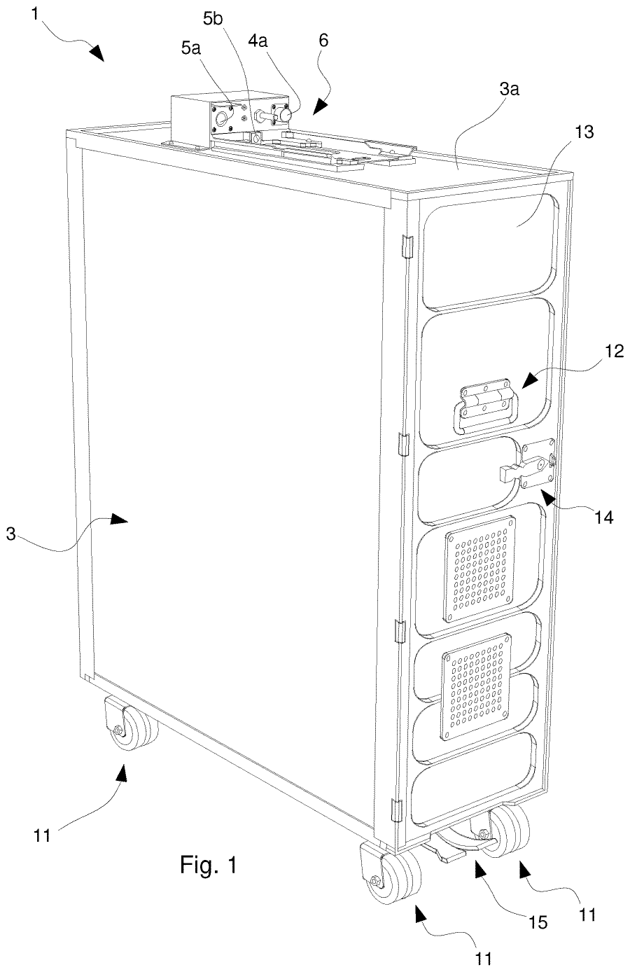

FIG. 1 is a perspective view of the test apparatus according to the invention;

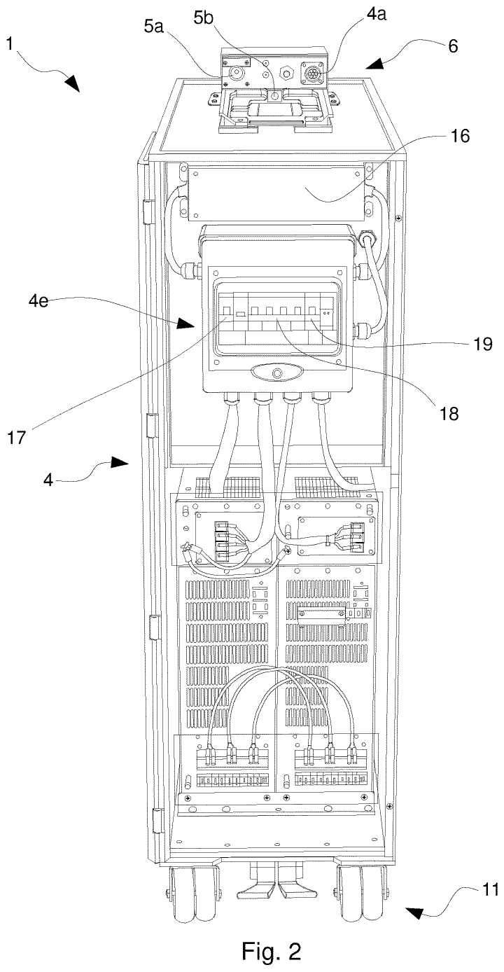

FIG. 2 is a front perspective view of the test apparatus;

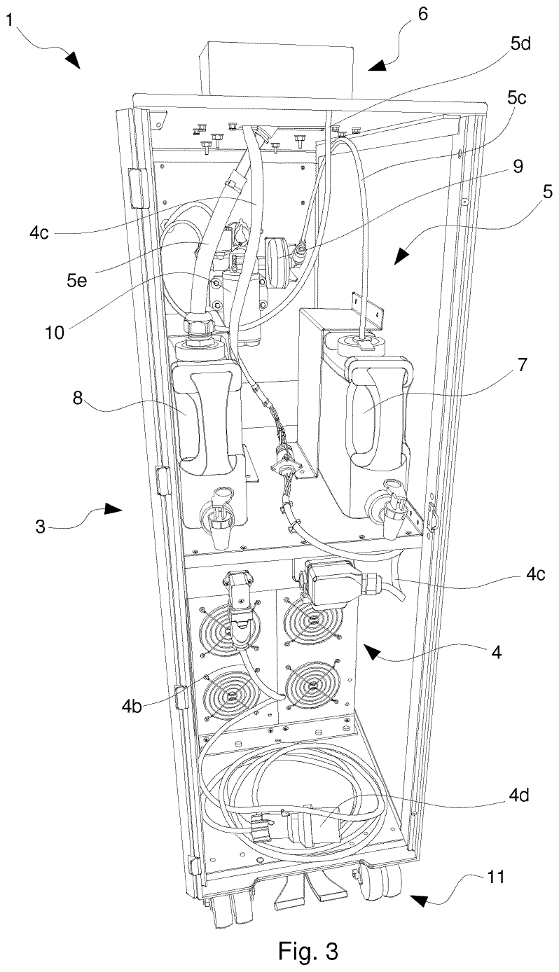

FIG. 3 is a rear perspective view of the test apparatus;

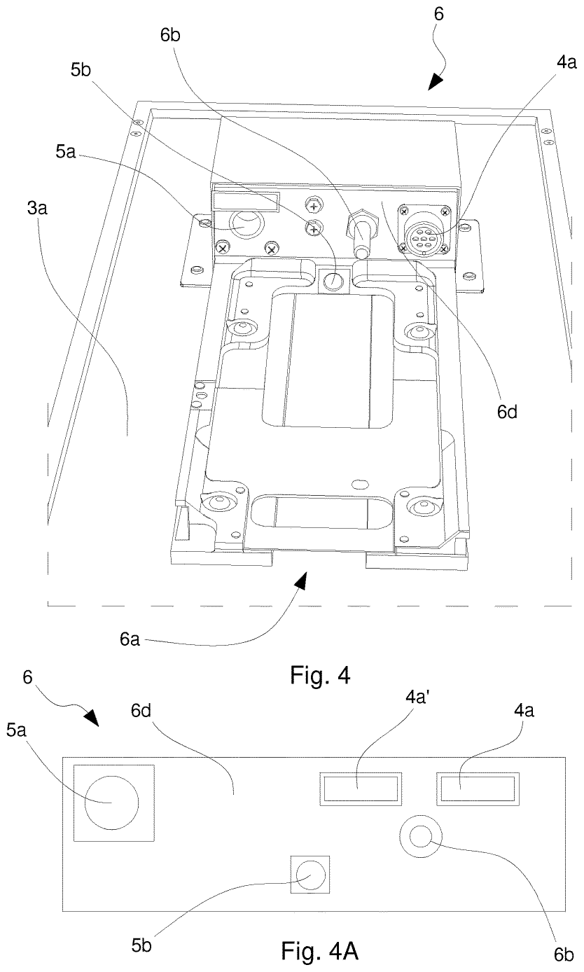

FIG. 4 is a perspective view of a detail of a portion of a first variant of the test apparatus;

FIG. 4A is a schematic front view of a portion of a second variant of the test apparatus;

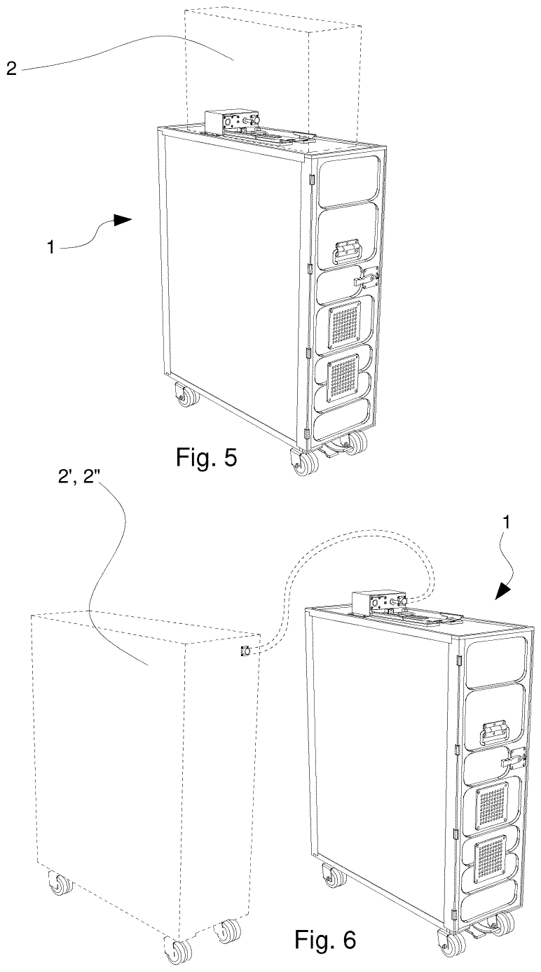

FIG. 5 is a schematic perspective view of the test apparatus connected to a user device;

FIG. 6 is a schematic perspective view of the test apparatus connected to a user device different from that of FIG. 5.

### DETAILED DESCRIPTION

With reference to the figures mentioned above, a test apparatus for simulating actual supply conditions of a vehicle in order to test user devices 2, 2′, 2″ intended to operate on board the vehicle is indicated as a whole by reference numeral 1.

The illustrated version of the test apparatus 1 is used to simulate the electrical and hydraulic supply conditions that may be found on board a vehicle.

The term “vehicle” is intended to mean any means of transport, in particular one intended for transporting people.

In the following description, explicit reference will be made to the use of the test apparatus with user devices 2, 2′, 2″ employed in an aeroplane, without thereby losing generality.

Such user devices 2, 2′, 2″ may, in addition to aeronautical use, also be used in the nautical field (for example on a yacht), or in the terrestrial field (such as a camper van), and the like.

Such user devices 2, 2′, 2″ include, by way of non-limiting example, a beverage-preparation apparatus 2 (for example a coffee machine), an electric oven 2′ (for example an induction oven) for preparing meals, a waste compactor 2″, and the like (FIGS. 5 and 6).

The test apparatus 1 for simulating actual supply conditions of a vehicle includes a portable support body 3 and an electrical supply unit 4 integrated into the support body 3 (FIGS. 1, 2, 3 and 4). The electrical supply unit 4 is configured to electrically supply one or more user devices 2, 2′, 2″ according to controllable and settable operating parameters so as to simulate the same electrical supply conditions present on the vehicle.

The controllable (electrical) operating parameters include a type of voltage (direct or alternating), a voltage value, and/or a supply frequency.

The test apparatus 1 further includes a hydraulic supply-discharge unit 5 integrated into the support body 3 (FIG. 3). The hydraulic supply-discharge unit 5 is configured to supply water to a user device 2 according to further controllable and settable operating parameters so as to simulate the same supply-discharge conditions present on the vehicle, and to recover water used by the user device 2.

The further (hydraulic) operating parameters include a supply pressure. The further (hydraulic) operating parameters may also include a supply flow rate.

In the illustrated version, the hydraulic supply-discharge unit 5 is coupled to the beverage-preparation machine 2 (shown in dashed lines in FIG. 5). This user device 2 may indeed be connected to a water system (supply and discharge) for correct operation.

In the illustrated version, the electrical supply unit 4 may be coupled to one of the user devices 2, 2′, 2″ directly (FIG. 5) or via an extension cable (FIG. 6).

In order to further reduce the overall dimensions and improve the transportability of the test apparatus 1, the illustrated version allows the supply of only one user device at a time (FIGS. 5 and 6).

However, in a non-illustrated version, the test apparatus 1 may allow simultaneous operation of multiple user devices 2, 2′, 2″.

In the illustrated version, the support body 3 is configured as a casing body 3 (hollow) that houses the electrical supply unit 4 and the hydraulic supply-discharge unit 5 (FIGS. 2 and 3). The casing body 3 of this illustrated version is shaped as a movable carriage body provided with wheels 11 for advancement and a handle 12 for moving the test apparatus 1 and/or for opening one of the doors 13 by a user (FIG. 1). In this illustrated version, the casing body 3 has a parallelepiped structure (typical of a service trolley used on board an aeroplane).

In this version, the carriage body is also provided with stationary brake elements 15 configured to lock and unlock rotation of the wheels 11 (FIG. 1). In this illustrated version, the brake elements 15 are of the pedal type (in particular of the double-pedal type).

In the illustrated version, the casing body 3 is provided with internal (prismatic) compartments arranged to house respectively the electrical supply unit 4 and the hydraulic supply-discharge unit 5 (FIG. 3). In this illustrated version, the internal compartments are accessible through one or more doors 13 that close respectively a front portion and a rear portion of the parallelepiped structure (FIG. 1). The casing body 3 of the illustrated version is also provided, for each door 13, with a safety-closure mechanism 14 arranged to lock closure of the respective door 13 (FIG. 1) and to allow access to the electrical supply unit 4 and/or to hydraulic supply-discharge unit 5.

In the illustrated version, the casing body 3 includes a front compartment shaped to house the electrical supply unit 4 (FIG. 2).

In the illustrated version, the casing body 3 includes a rear compartment shaped to house the hydraulic supply-discharge unit 5 (FIG. 3). In this version, the front compartment is positioned in an upper zone of the casing body 3.

In a non-illustrated version, the electrical supply unit 4 and the hydraulic supply-discharge unit 5 may be housed in the casing body 3 in a different arrangement.

In a non-illustrated version, the support body may be shaped as a suitcase.

In the illustrated version, the hydraulic supply-discharge unit 5 includes water-supply and water-discharge connecting elements 5a, 5b provided on the support body 3. These water-supply and water-discharge connecting elements 5a, 5b are configured to supply water to the user device 2 (in this specific case, the beverage-preparation machine) and to remove discharge water from the user device 2 (FIGS. 1, 2, 4 and 4A).

In the illustrated version, the water-supply and water-discharge connecting elements 5a, 5b include two hydraulic couplings (a first hydraulic coupling 5a for supply and a second hydraulic coupling 5b for discharge).

In a non-illustrated version, the water-supply and water-discharge connecting elements may include two end portions of respective hydraulic pipes (a first end portion for supply and a second end portion for discharge).

In the illustrated version, the water-supply and water-discharge connecting elements 5a, 5b include a water-supply connecting element 5a arranged to supply (output) water to the user device 2, and a water-discharge connecting element 5b arranged to receive (input) discharge water from the user device 2. As will be detailed later, in the illustrated version the water-supply and water-discharge connecting elements 5a, 5b are connected to tank elements.

In the illustrated version, the electrical supply unit 4 includes electrical supply connecting elements 4a provided on the support body 3 (FIGS. 1, 2 and 4). These electrical supply connecting elements 4a are configured to electrically supply the one or more user devices 2, 2′, 2″. In the illustrated version, the electrical supply connecting elements include an electrical terminal 4a and one or more electrical output conductors 4c (electrical cables) arranged to connect the electrical supply unit 4 (via the electrical connector 4a) to the one or more user devices 2, 2′, 2″.

The electrical supply unit 4 furthermore includes one or more electrical input connectors 4b, 4d arranged to draw power from the electrical network. In this illustrated version, one or more electrical input conductors 4b include an electrical cable connected to the transformer device and a plug 4d suitable to be inserted into a corresponding electrical socket (for example of domestic or industrial type).

The electrical supply unit 4 is configured, in particular, to be supplied (at the input) selectively according to the European electrical standard (220-230 V, 50 Hz) and the US standard (120 V, 60 Hz).

The electrical supply unit 4 is configured, in particular, to be supplied (at the input) selectively with single-phase electric current or with three-phase electric current.

In the variant illustrated in FIG. 4A, the test apparatus 1 further includes transmission-connector elements 4a′ provided on the support body 3 for transmitting electrical signals between the user device 2, 2′, 2″ and a control unit (CU) configured to control the user device 2, 2′, 2″. In this variant, the transmission-connector elements include a signal electrical connector 4a′. In particular, the signal electrical connector 4a′ includes a CAN-BUS connector.

In a non-illustrated version, this control unit is provided in the support body 3.

The test apparatus 1 includes, in particular, a user-interface block 6 mounted on the support body 3.

In the variant illustrated in FIGS. 1-4, the user-interface block 6 supports, in particular, the water-supply and water-discharge connecting elements 5a, 5b and the electrical supply connecting elements 4a.

In the variant illustrated in FIG. 4A, the user-interface block 6 supports, in particular, the water-supply and water-discharge connecting elements 5a, 5b, the electrical supply connecting elements 4a, and the electrical-signal connecting elements 4a′.

In the illustrated version, the user-interface block 6 is mounted on (and integral with) a top portion 3a of the support body 3 (that is, a top portion of the parallelepiped structure).

In the illustrated version, the user-interface block 6 is provided with guiding and centring elements 6a, 6b shaped to guide the positioning of the user device 2 relative to the water-supply and water-discharge connecting elements 5a, 5b and to the electrical supply connecting elements 4a, and to centre the user device 2 relative to the latter.

In the illustrated version, the guiding and centring elements 6a, 6b include a slide portion 6a shaped to guide positioning of the user device 2, and a centring pin element 6b shaped to centre the user device 2. In this illustrated version, the centring pin element 6b protrudes parallel to the slide portion 6a. The slide portion 6a includes a pair of equipped rails, parallel to each other and integral with the support body 3. The slide portion is fixed, by fastening elements, to the top portion of the support body 3.

In the illustrated version, the water-supply and water-discharge connecting elements 5a, 5b, the electrical supply connecting elements 4a and the centring pin 6b are positioned on a support wall 6d formed on the user-interface block 6 and extending with a substantially vertical surface (FIG. 4).

The slide portion 6a extends horizontally and perpendicularly to the support wall 6d.

In other words, the user-interface block 6 is shaped as an “L”, the shorter side of which is provided with the slide portion 6a, and the longer side of which is provided with the support wall 6d.

The user-interface block 6 is shaped so as to create a form fit with a corresponding interface portion (slide portion) provided on the base of the user device 2 (schematically shown in dashed lines in FIG. 5). This interface portion includes electrical-supply connections (not illustrated) and hydraulic connections (not illustrated), which, in a mounted configuration in which the user-interface block 6 and the user device 2 are assembled (as schematically shown in FIG. 5), are connected respectively to the electrical supply connecting elements 4a and to the water-supply and water-discharge connecting elements 5a, 5b. The centring pin 6b is further arranged to interact in contact with corresponding centring-hole provided in the interface portion of the user device 2.

With regard to the user-interface block 6 provided with the electrical-signal connecting elements 4a′ (FIG. 4A), the corresponding user devices include a matching interface portion, that is, including an electrical signal connection corresponding to the electrical-signal connecting elements 4a′. In this illustrated variant, the electrical-signal connecting elements 4a′ and the electrical-supply connecting elements 4a are arranged side by side on the support wall 6d.

In the illustrated version, the hydraulic supply-discharge unit 5 includes a tank supplying element 7 for storing supply water to be provided to the user device 2, and tank discharging element 8 for storing discharge water coming from the user device 2.

In a non-illustrated version, the hydraulic supply-discharge unit 5 includes presence and level sensors for detecting the presence and a level of water contained respectively in the tank supplying element 7 and in the tank discharging element 8. The presence and level sensors may be associated with a warning light to signal the presence and level of the water.

As mentioned, in the illustrated version, the water-supply connecting element 5a are connected to the tank supplying element 7, and the water-discharge connecting element 5b are connected to the tank discharging element 8 via respective pipes.

In the illustrated version, the hydraulic supply-discharge unit 5 includes a pump 9 in fluid connection with the tank supplying element 7 and the water-supply connecting element 5a. The pump 9 is configured to draw water from the tank supplying element 7 and to convey it to the water-supply connecting element 5a to make it available to the user device 2 according to the further operating parameters. In this way, it is possible to provide, at the water-supply connecting element 5a, the same water-supply conditions present on the vehicle. In the illustrated version, the pump 9 is a suction pump.

The operating pressure provided to the water-supply connecting element 5a (by the pump 9) is between 1 and 3 bar, in particular between 1.5 and 2.5 bar, and specifically 2 bar.

In the illustrated version, the hydraulic supply-discharge unit 5 includes a filter element 10 interposed between the pump 9 and the water-supply connecting element 5a so as to filter undesirable substances present in the supply water.

In the illustrated version, the filter element 10 includes an anti-limescale filter.

In the illustrated version, the pump 9 and the filter element 10 are connected to one another to form a single pump-filter unit. In a non-illustrated version, the pump 9 and the filter element 10 are connected by means of a respective pipe.

In the illustrated version, the water-supply and water-discharge connecting elements 5a, 5b include a first pipe 5c hydraulically connecting the tank supplying element 7 to the pump 9 (at the suction section of the pump 9), and a second pipe 5d hydraulically connecting the filter element 10 (that is, an outlet port of the filter element 10) to the water-supply connecting element 5a.

In a non-illustrated version, no filter element 10 may be provided. In this non-illustrated version, a first pipe is provided connecting the tank supplying element 7 to the suction of the pump 9, and a second pipe is provided connecting the delivery of the pump 9 (directly) to the water-supply connecting element 5a.

In the illustrated version, the water-discharge connecting element 5b is hydraulically (directly) connected to the tank discharging element 8 via a third pipe 5e.

In the illustrated version, the electrical supply unit 4 includes an electrical transformer device configured to transform electrical energy drawn from the electrical supply network according to predetermined operating parameters so as to provide at the output, that is, at the electrical supply connecting elements 4a, the same electrical-supply conditions present on the vehicle.

The electrical supply unit 4 is adjustable in output voltage and frequency and furthermore includes one or more electrical selectors configured to select a desired output voltage and frequency at the electrical supply connecting elements 4a on the basis of the supply conditions of the vehicle to be simulated.

The electrical supply unit 4 can provide at the output (to the electrical supply connecting elements 4a) a direct voltage of 14 V or 28 V.

The electrical supply unit 4 can provide at the output (to the electrical supply connecting element 4a) a single-phase alternating voltage of 115 V at a frequency of 400 Hz.

The electrical supply unit 4 is configured, in particular, to supply a pump-supply voltage to the pump 9 by means of a transformation sub-unit 16 (FIG. 2). In one version, the pump-supply voltage may be different from that provided at the output to the electrical supply connecting elements 4a and may in particular be 12 V or 24 V (direct current).

In the illustrated version, the electrical supply unit 4 is provided with a control panel 4e including a series of electrical switches (FIG. 2).

In the illustrated version, the control panel 4e includes a main switch 17 for the input supply to the electrical supply unit 4, a safety switch 18 configured to disconnect the electrical supply entering and leaving the electrical panel 4e and thus to supply or disconnect selectively the electrical supply connecting elements 4a. In this illustrated version, the control panel 4e further includes a supply switch 19 for the pump 9 (FIG. 2).

Thanks to the specific configuration of the electrical supply unit 4 and of the hydraulic supply-discharge unit 5, it is possible to simulate the actual supply conditions available on board a vehicle and to enable operation of any user device intended to operate on board the vehicle in an environment external to the vehicle.

The test apparatus 1, thanks to the configuration of the support body 3, is relatively compact and lightweight, making the test apparatus 1 extremely flexible when it must be transported and used in different locations, for example to follow temporary events (fairs or exhibitions) for demonstrating the operation of the aforesaid user devices. In particular, the apparatus 1 is suitable for testing the user device 2 intended for preparing certain beverages, such as coffee, where the use of water is required, without the need to connect to a water supply network.

Furthermore, the test apparatus 1 is easy to use for an unskilled operator, since—thanks to the configuration of the electrical supply unit 4 and in particular of the electrical panel 4e—it has limited possibilities for adjusting the electrical supply and the hydraulic supply, which may be selected intuitively by means of the one or more selectors and/or switches depending on the type of vehicle to be simulated.

The test apparatus 1 is therefore capable of faithfully simulating the actual supply conditions of a vehicle so as to test user devices intended to operate on board the vehicle, thereby improving their performance and the quality of the service or product provided by such user devices. Indeed, the ease of use of the test apparatus 1 makes it possible to create recipes and to test cooking methods for food and preparation methods for beverages directly on the user devices 2, 2′ intended to operate on board the vehicle, with the result that the food conceived, prepared and optimised using such user devices 2, 2′ has physical characteristics (temperature distribution, humidity, consistency) and organoleptic (aromatic) characteristics identical to those of the corresponding food prepared on board the vehicle.

1. A test apparatus for simulating supply conditions of a vehicle to test user devices intended to operate on board the vehicle, including:
a portable support body,
an electrical supply unit integrated into the portable support body and configured to supply electrically one or more user devices according to controllable and settable operating parameters so as to simulate the same electrical supply conditions present in the vehicle,
a hydraulic supply-discharge unit integrated into the portable support body and configured to supply water to a user device of the one or more user devices according to further operating parameters that are controllable and settable so as to simulate the same supply-discharge conditions present in the vehicle, and to recover water used by the user device.

2. The test apparatus according to claim 1, wherein the hydraulic supply-discharge unit includes water-supply and water-discharge connecting elements provided on the portable support body, the water-supply and water-discharge connecting elements being configured to supply water to the user device and remove discharge water from the user device.

3. The test apparatus according to claim 1, wherein the electrical supply unit includes electrical supply connecting elements provided on the portable support body, the electrical supply connecting elements being configured to supply electrically the one or more user devices.

4. The test apparatus according to claim 2, and including a user-interface block that supports the water-supply and water-discharge connecting elements and the electrical supply connecting elements, the user-interface block being fitted to the portable support body.

5. The test apparatus according to claim 4, wherein the user-interface block is fitted to a top portion of the portable support body.

6. The test apparatus according to claim 4, wherein the user-interface block is provided with guiding and centring elements shaped to guide positioning of, and to centre, the user device with respect to the water-supply and water-discharge connecting elements and to the electrical supply connecting elements.

7. The test apparatus according to claim 6, wherein the guiding and centring elements include a slide portion shaped to guide the positioning of the user device with respect to the water-supply and water-discharge connecting elements and to the electrical supply connecting elements, and a centring pin element shaped to centre the user device with respect to the water-supply and water-discharge connecting elements and to the electrical supply connecting elements.

8. The test apparatus according to claim 2, wherein the hydraulic supply-discharge unit includes a tank supplying element for storing supply water and a tank discharging element for storing discharge water, and wherein the water-supply and water-discharge connecting elements include water-supply and water-discharge connecting elements connected to the tank supplying element and water-discharge connecting elements connected to the tank discharging element.

9. The test apparatus according to claim 8, wherein the hydraulic supply-discharge unit includes a pump fluidly connected with said tank supplying element and the water-supply connecting elements, the pump being configured to remove water from the tank supplying element and convey the water up to the water-supply connecting elements according to the further operating parameters so as to provide, at the water-supply connecting elements, the same water-supplying conditions present in the vehicle.

10. The test apparatus according to claim 9, wherein the hydraulic supply-discharge unit includes a filter element interposed between the pump and the water-supply connecting elements to filter the supply water.

11. The test apparatus according to claim 1, wherein the electrical supply unit includes an electric transformer device configured to transform electric energy taken from an electrical supply network according to the operating parameters so as to provide, at the electrical supply connecting elements, the same output electrical supply conditions present in the vehicle.

12. The test apparatus according to claim 1, wherein the output voltage and frequency of the electrical supply unit are adjustable and the electrical supply unit includes one or more electric selectors configured to select and set a desired output voltage and frequency at the electrical supply connecting elements on the basis of the type of vehicle to be simulated.

13. The test apparatus according to claim 1, wherein the support body is configured as a casing body that houses the electrical supply unit and hydraulic supply-discharge unit, and wherein the casing body is shaped as a movable carriage body provided with wheel for advancement and handle elements for handling by a user.

14. The test apparatus according to claim 4, wherein transmission connecting elements for transmitting electric signals is provided in the user-interface block.
